(19) United States
(12) Patent Application Publication
(10) Pub. No.: US 2013/0260575 A1
(43) Pub. Date: Oct. 3, 2013

(54) SILICON PRECURSORS AND COMPOSITIONS COMPRISING SAME FOR DEPOSITING LOW DIELECTRIC CONSTANT FILMS

(71) Applicant: AIR PRODUCTS AND CHEMICALS, INC., Allentown, PA (US)

(72) Inventors: Jennifer Elizabeth Antoline Al-Rashid, Bethlehem, PA (US); Raymond Nicholas Vrtis, Orefield, PA (US); Irene Joann Hsu, Conshohocken, PA (US)

(73) Assignee: AIR PRODUCTS AND CHEMICALS, INC., Allentown, PA (US)

(21) Appl. No.: 13/773,931

(22) Filed: Feb. 22, 2013

Related U.S. Application Data
(60) Provisional application No. 61/616,628, filed on Mar. 28, 2012.
(60) Provisional application No. 61/617,351, filed on Mar. 29, 2012.

(51) Int. Cl. H01L 21/02

(52) U.S. Cl. CPC H01L 21/02203
USPC 438/789; 106/122

(57) ABSTRACT

A chemical vapor deposition method for producing a porous organosilica glass film comprising: introducing into a reaction chamber gaseous reagents comprising a porogenated precursor; optionally a structure former precursor selected from the group consisting an organosilane, an organosiloxane, and combinations thereof; and optionally a porogen precursor; applying an energy source to the gaseous reagents in the chamber to induce reaction of the gaseous reagents to deposit a preliminary film on the substrate, wherein the preliminary film contains the porogen; and removing from the preliminary film at least a portion of the porogen to provide the porous film with pores and a dielectric constant less than 2.6.

### CROSS REFERENCE TO RELATED APPLICATIONS

This patent application claims the benefit of prior U.S. Provisional Patent Application Ser. No. 61/616,628 filed Mar. 28, 2012 and Ser. No. 61/617,351 filed Mar. 29, 2012.

### BACKGROUND OF THE INVENTION

Described herein are silicon-containing precursors and compositions comprising same for depositing low dielectric constant (e.g., low k) materials or films produced by chemical vapor deposition (CVD) or atomic layer deposition (ALD) methods. More specifically, described herein are compositions and methods for making low k, porous films of such materials and their application for use, such as but not limited to, insulating layers in electronic devices.

The electronics industry uses dielectric materials as insulating layers between circuits and components of integrated circuits (IC) and associated electronic devices. Line dimensions are being reduced in order to increase the speed and memory storage capability of microelectronic devices (e.g., computer chips). As the line dimensions decrease, the insulating requirements for the interlayer dielectric (ILD) become much more rigorous. Shrinking the spacing requires a lower dielectric constant to minimize the RC time constant, where R is the resistance of the conductive line and C is the capacitance of the insulating dielectric interlayer. The value of C is inversely proportional to spacing and proportional to the dielectric constant (k) of the interlayer dielectric (ILD). Conventional silica (SiO₂) CVD dielectric films produced from SiH₄ or TEOS (Si(OCH₂CH₃)₄, tetraethylorthosilicate) and O₂ have a dielectric constant k greater than 4.0. There are several ways in which the industry has attempted to produce silica-based CVD films with lower dielectric constants, the most successful being the doping of the insulating silicon oxide film with organic groups providing dielectric constants in the range of 2.7-3.5. This organosilica glass is typically deposited as a dense film (density 1.5 g/cm³) from an organosilicon precursor, such as a methylsilane or siloxane, and an oxidant, such as O₂ or N₂O. Organosilica glass will herein be referred to as OSG. As dielectric constant or “k” values drop below 2.7 with higher device densities and smaller dimensions, the industry has exhausted most of the suitable low k compositions for dense films and has turned to various porous materials for improved insulating properties.

The patents and applications which are known in the field of porous ILD by CVD or other methods include: EP 1 119 035 A2 and U.S. Pat. No. 6,171,945, which describe a process of depositing an OSG film from organosilicon precursors with labile groups in the presence of an oxidant such as N₂O and optionally a peroxide, with subsequent removal of the labile group with a thermal anneal to provide porous OSG; U.S. Pat. Nos. 6,054,206 and 6,238,751, which teach the removal of essentially all organic groups from deposited OSG with an oxidizing anneal to obtain porous inorganic SiO₂; EP 1 037 275, which describes the deposition of an hydrogenated silicon carbide film which is transformed into porous inorganic SiO₂ by a subsequent treatment with an oxidizing plasma; and U.S. Pat. No. 6,312,793 B1, WO 00/24050, and a literature article Grill, A. Patel, V. Appl. Phys. Lett. (2001), 79(6), pp. 803-805, which all teach the co-deposition of a film from an organosilicon precursor and an organic compound, and subsequent thermal anneal to provide a multiphase OSG/organic film in which a portion of the polymerized organic component is retained. In these latter references, the ultimate final compositions of the films indicate residual porogen and a high hydrocarbon film content (80-90 atomic %). It is preferable that the final film retain the SiO₂-like network, with substitution of a portion of oxygen atoms for organic groups.

Applicants' previous filed patents, such as, for example U.S. Pat. Nos. 6,846,515; 7,098,149; 7,332,445; 7,384,471; 7,404,990; 7,943,195 describe particular compositions and methods incorporating same for depositing low dielectric constant films which include structure former precursors such as organosilane and/or organosiloxane precursors, porogen precursors, porogenated precursors, and combinations thereof to provide porous low dielectric constant films.

U.S. Pat. No. 7,491,658 describes a method for fabricating a SiCOH dielectric material comprising Si, C, O, and H atoms from a single organosilicon precursor with a built-in organic porogen provided.

U.S. Publ. No. 2011/0206857 describes the use of an organosilicon compound that comprises a silicon atom and a porogen component bonded to the silicon atom to provide a low dielectric constant layer.

Many IC manufacturers are currently integrating porous organosilicate glasses (OSG's) with a dielectric constant of 2.4-2.5 as back-end-of-line (BEOL) interconnect dielectrics. These materials include porosity ranging from 24 to 31 percent porosity as measured by Elliposmetric Porosimetry (EP) using the solvent toluene as the probe molecule. Next generation materials will need to have dielectric constants ranging from 2.0 to 2.3 which are considered ultra low dielectric constant materials. In order to achieve such ultra low dielectric constant materials, future OSG materials will likely need to incorporate more porosity. However, at greater levels of porosity, unresolved issues of optimizing pore interconnectivity and pore size distribution remain. As discussed above, a number of options to control the network skeleton and pore structure of OSG materials have been proposed which include the use of adding alternative silicon-containing precursors and/or alternative porogen precursors. In all of these options, there is a need to balance such pore structure modification with critical film properties such as dielectric constant and mechanical strength.

### BRIEF SUMMARY OF THE INVENTION

The present invention described herein provides a composition and method for depositing a porous low dielectric constant material or film with the requisite balance of pore structure, porosity, pore interconnectedness, and pore diameter ranges with important material or film properties such as dielectric constant and mechanical strength. Described herein are low dielectric constant material or film which are formed by a chemical vapor deposition or atomic layer deposition method in which a preliminary film is deposited from a composition comprising a porogenated precursor; optionally at least one porogen precursor; and optionally at least one silica containing precursor selected from the group consisting of an organosilane, an organosiloxane, and mixtures thereof. The porogen contained within the composition (e.g., the porogen containing in the porogenated precursor and the optional separate porogen precursor(s)) is at least partially removed using one or more energy sources to provide the porous film. Depending upon the composition, the low dielectric constant film is deposited with an oxidant. In other embodiments, however, the film is deposited in absence of an oxidant.

In one aspect, there is provided a chemical vapor deposition method for producing a porous organosilica glass film represented by the formula SiᵥO_{w}CₓH_{y}F_{z}, where v+w+x+y+z=100%, v is from 10 to 35 atomic %, w is from 10 to 65 atomic %, x is from 5 to 30 atomic %, y is from 10 to 50 atomic % and z is from 0 to 15 atomic %, where the method comprises the following steps: providing a substrate within a reaction chamber; introducing into the reaction chamber gaseous reagents comprising a porogenated precursor comprising a silicon atom bonded to a porogen; optionally a structure former precursor selected from the group consisting of an organosilane and an organosiloxane; and optionally a porogen precursor wherein the porogen in the porogenated precursor comprises 10 carbon atoms or less; applying at least one energy source to the gaseous reagents in the reaction chamber to induce reaction of the gaseous reagents to deposit a preliminary film on the substrate, wherein the preliminary film contains the porogen; and removing from the preliminary film at least a portion of the porogen to provide the porous film with pores and a dielectric constant less than 2.6.

In another aspect, the present invention provides a composition for depositing porous low dielectric constant film comprising: (a)(i) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; (a)(ii) a structure former precursor selected from the group consisting of diethoxymethylsilane, dimethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trimethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof; and (b) a porogen precursor selected from the group consisting of: alpha-terpinene, limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes, bicycloheptadiene (BCHD), and decahydronaphthele.

In yet another aspect, the present invention provides a composition for depositing porous low dielectric constant film comprising: a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilylethyl)cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof. In this or other embodiments, the composition further comprises a structure former precursor. In an alternative embodiment, the composition further comprises a porogen precursor.

In a further aspect, the present invention provides a composition for depositing porous low dielectric constant film comprising: (a)(i) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and (a)(ii) a structure former precursor selected from the group consisting of diethoxymethylsilane, dimethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trim ethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof. In this or other embodiments, the composition further comprises a porogen precursor.

In still another aspect, the present invention provides a composition for depositing porous low dielectric constant film comprising: (a) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and (b) a porogen precursor selected from the group consisting of: alpha-terpinene, limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes, bicycloheptadiene (BCHD), and decahydronaphthele. In this or other embodiments, the composition further comprises a structure former precursor.

### BRIEF DESCRIPTION OF THE DRAWINGS

FIG. 1 illustrates the relationship between the dielectric constant and modulus for the following porogenated precursors: hexyltrimethoxysilane (HTMOS), cyclohexyltrimethoxysilane (CHTMOS), cyclohexylmethyldimethoxysilane (CHMDMOS), and n-butyltriethyoxysilane (nBTEOS). FIG. 1 compares the results against similar films deposited using the structure former precursor diethoxymethylsilane (DEMS) alone (see gray band on FIG. 1).

FIG. 2 illustrates the relationship between the SiMe/SiO ratio as measured by the Fourier Transform Infrared Spectroscopy (FT-IR) and weight percentage of porogenated precursor (e.g., hexyltriethoxysilane (HTEOS), HTMOS, nBTEOS, isobutyltriethoxysilane (iBTEOS), CHTMOS, CHMDMOS, and ethyltriethoxysilane (ETEOS) within a composition also comprising the structure former precursor DEMS wherein the weight percentage of porogenated precursor and DEMS combined added to 100 weight percent.

FIG. 3 illustrates the relationship between the decrease in CHx within the film as measured by FT-IR and weight percentage of porogenated precursor (e.g., hexyltriethoxysilane (HTEOS), HTMOS, nBTEOS, isobutyltriethoxysilane (iBTEOS), CHTMOS, CHMDMOS, and ethyltriethoxysilane (ETEOS) within a composition also comprising the structure former precursor DEMS wherein the weight percentage of porogenated precursor and DEMS combined added to 100 weight percent.

FIG. 4 is a comparison of the toluene uptake behavior which indicates the percentage porosity at low partial pressures indicated by P/Po for two dielectric films deposited using the porogenated precursors CHMDMOS and CHTMOS.

FIG. 5 illustrates the relationship between the SiMe/SiO ratio as measured by the FT-IR and weight percentage of porogenated precursor (CHTMOS and CHMDMOS) by itself (100% porogenated precursor) and in combination with an additional structure former diethoxymethylsilane (DEMS) at different weight percentages wherein the weight percentage of porogenated precursor and DEMS combined added to 100 weight percent both with additional porogen (labeled as ‘+ATRP’) and without (labeled as ‘Dense’)

FIG. 6 illustrates the relationship between the ratio of CHx/SiO within the film as measured by FT-IR and weight percentage of porogenated precursor (CHTMOS and CHMDMOS) by itself (100% porogenated precursor) and in combination with the an additional structure former diethoxymethylsilane DEMS at different weight percentages wherein the weight percentage of porogenated precursor and DEMS combined added to 100 weight percent both with additional porogen (labeled as ‘+ATRP’) and without (labeled as Dense').

FIG. 7 provides a comparison of distribution of the pore radius in nanometers (nm) for compositions of porogenated precursor (CHTMOS and CHMDMOS) by itself (100% porogenated precursor) and in combination with the additive or porogen precursor alpha-terpinene (ATRP) at 30 weight percent of the porogenated precursor (CHTMOS or CHMDMOS).

FIG. 8 is a comparison of the toluene uptake behavior which indicates the percentage porosity at low partial pressures indicated by P/Po for four films deposited using the porogenated precursors CHMDMOS and CHTMOS alone and in combination with the additive or porogen precursor ATRP at 30 weight percentage of the porogenated precursor.

FIG. 9 provides a comparison of the porosity versus pore radius in nanometers for various films deposited using the following compositions: CHMDMOS, CHTMOS, DEMS/ATRP in a 30/70 weight percentage mixture, CHMDMOS/ATRP, and CHMDMOS/ATRP.

FIG. 10 shows the relationship between modulus as measured by gigapascal (GPa) or mechanical properties vs. dielectric constant for various films deposited using the following combinations: DEMS/porogenated precursor/ATRP; DEMS/ATRP; and porogenated precursor/ATRP.

FIG. 11 is a comparison of the toluene uptake behavior which indicates the percentage porosity at low partial pressures indicated by P/Po for five films deposited using the porogenated precursors CHMDMOS and CHTMOS in combination with the additive or porogen precursor ATRP; CHMDOS and CHTMOS in combination with DEMS and ATRP; and DEMS/ATRP.

FIG. 12 provides a comparison of the porosity versus pore radius in nanometers for various films deposited using the following compositions: DEMS/ATRP in a 30/70 weight percentage mixture, CHMDMOS/ATRP, CHTMOS/ATRP, DEMS/CHMDMOS/ATRP, DEMS/CHTMOS/ATRP, and DEMS/ATRP for an optimized 2.2 dielectric constant film.

FIG. 13 provides a comparison of distribution of the pore radius in nanometers (nm) for compositions of porogenated precursor (CHTMOS and CHMDMOS) in combination with the additive or porogen precursor alpha-terpinene (ATRP) and further in combination with the structure former precursor DEMS wherein the weight ratio of porogenated precursor, DEMS, and ATRP is 15/15/70.

### DETAILED DESCRIPTION OF THE INVENTION

Organosilicates are candidates for low k materials, but without the addition of porogens to add porosity to these materials, their inherent dielectric constant is limited to as low as 2.7. The addition of porosity, where the void space has an inherent dielectric constant of 1.0, reduces the overall dielectric constant of the film, generally at the cost of mechanical properties. Materials properties depend upon the chemical composition and structure of the film. Since the type of organosilicon precursor has a strong effect upon the film structure and composition, it is beneficial to use precursors that provide the required film properties to ensure that the addition of the needed amount of porosity to reach the desired dielectric constant does not produce films that are mechanically unsound. There is an increasing need to provide methods and compositions for generating smaller pores and tighter pore size distributions in a low dielectric constant film as a means to overcome excessive film damage during integration. However, smaller pores and tighter pore size distributions within the films which may negatively impact other film properties such as mechanical properties. Thus, the invention provides the means to generate porous OSG films that have a desirable balance of electrical and mechanical properties. Other film properties often track with electrical or mechanical properties.

Preferred embodiments of the invention provide a thin film material having a low dielectric constant and improved mechanical properties, thermal stability, and chemical resistance (to oxygen, aqueous oxidizing environments, etc.) relative to other porous organosilica glass materials. This is the result of the incorporation into the film of carbon (preferably predominantly in the form of organic carbon, —CHₓ, where x is 1 to 3, more preferably the majority of C is in the form of —CH₃) whereby specific precursor or network-forming chemicals are used to deposit films in an environment free of oxidants (other than the optional additive/carrier gas CO₂, to the extent it is deemed to function as an oxidant). However, in other embodiments, the precursors may be deposited in oxygen-containing environments.

The materials and films described herein can be provided by adding pore-forming species or porogens to the deposition procedure, incorporating the porogens into the as-deposited (i.e., preliminary) OSG film and removing substantially the porogen such as the hydrocarbon species from the preliminary film while substantially retaining the terminal Si—CH₃ groups of the preliminary film to provide the product film. The product film is a porous OSG film and has a dielectric constant reduced from that of the preliminary film as well as from an analogous film deposited without porogens. The films described herein as porous OSG differ from porous inorganic SiO₂, the latter of lacks the hydrophobicity provided by the organic groups in OSG.

Silica produced by PE-CVD TEOS has an inherent free volume pore size determined by positron annihilation lifetime spectroscopy (PALS) analysis to be about 0.6 nm in equivalent spherical diameter. The pore size of the films described herein as determined by small angle neutron scattering (SANS) or PALS is 5 nanometers (nm) in equivalent spherical diameter or less, 2.5 nm in equivalent spherical diameter or less, or 1.5 nm in equivalent spherical diameter or less. In certain embodiments described herein, the range of pore sizes within the inventive film has one or more of the following end points: 0.1, 0.2, 0.3, 0.4, 0.5, 0.6, 0.7, 0.8, 0.9, 1.0, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, 3.0, 3.1, 3.2, 3.3, 3.4, 3.5, 3.6, 3.7, 3.8, 3.9, 4.0, 4.1, 4.2, 4.3, 4.4, 4.5, 4.6, 4.7, 4.8, 4.9, or 5.0. In one particular embodiment, the pore sizes range from about 1.0 to about 1.5 nm.

Total porosity of the film may range from 5 to 75%, or from 10 to 60%, or from 15 to 40% or from 20 to 35% or from 20 to 30%, depending upon the process conditions and the desired final film properties. In certain embodiments described herein, the range of porosity within the inventive film has one or more of the following end points: 5, 10, 15, 20, 25, 30, 35, 40, 45, 50, 55, 60, 65, 70, or 75%. The porosity of the film need not be homogeneous throughout the film. In certain embodiments, there is a porosity gradient and/or layers of varying porosities. Such films can be provided by, e.g., adjusting the ratio of porogen to precursor during deposition.

Films of the invention preferably have a density of less than 2.0 g/cm³, or alternatively, less than 1.5 g/cm³ or less than 1.25 g/cm³. Preferably, films of the invention have a density at least 10% less than that of an analogous OSG film produced without porogens, more preferably at least 20% less.

As previously mentioned, the method and composition described herein uses at least one porogenated precursor in addition to at least one structure-former precursor and optionally at least one separate porogen precursor to provide the material described herein. Precursors containing porogens bound to them are sometimes referred to hereinafter as “porogenated precursors”. Porogenated precursors as defined herein are molecules where the structure-forming precursor and the pore-forming precursor are not necessarily different molecules, and in certain embodiments, the porogen is a part of (e.g., covalently bound to) the structure-forming precursor. While not being bound to theory, there may be several reasons to use a porogenated precursor, in lieu of, or in addition to, a separate structure-former precursor and a separate porogen precursor. One reason is that the silicon atoms can be incorporated easily into the growing SiO₂ network during deposition because of the ease of forming a SiO network and thus the Si facilitates incorporation of the sacrificial porogen group. The second reason is that a sacrificial porogen bonded to a silicon atom in the porogenated precursor is relatively small relative to the pores which have been measured in comparative low dielectric constant films deposited using a separate structure-former and separate porogen precursors. In certain embodiments described herein, the porogen bonded to the silicon atom in the porogenated precursor comprises 10 carbon atoms or less such as, without limitation, methyl, ethyl, propyl, isopropyl, butyl, isobutyl, tert-butyl, sec-butyl, pentyl, cyclopentyl, isopentyl, hexyl, cyclohexyl, octyl, and cyclooctyl groups. The carbon containing group on the porogenated precursor can be a linear, branched, cyclic, saturated or unsaturated, substituted or unsubstituted group. In certain embodiments, the size of the porogen bonded to the silicon atom allows the precursor to be of sufficient volatility for a PECVD process.

If one was to consider a pore to be a sphere of uniform size, for a given defined space, there is a limit to how many spheres can fit into a space before you have to start overlapping spheres (this could be considered interconnectivity in which pores begin to overlap at, for example, about ˜35% porosity or greater). Thus, there is a theoretical limit as to the number of spheres you can fit into a space (% porosity) before one would start breaking down the material (e.g., decreasing the interconnectivity of the network). Conversely, it is known that in order to pack the largest volume of spheres into a space, one should use spheres of varying size in order to maximize the volume of spheres (i.e., porosity). Accordingly, in order to obtain the greatest porosity (and by application the lowest dielectric constant), one should use pores of differing size. Therefore, using a smaller porogen that is bonded to a silicon atom in addition to one or more separate precursors, one can get additional porosity in a given film without increasing pore interconnectivity.

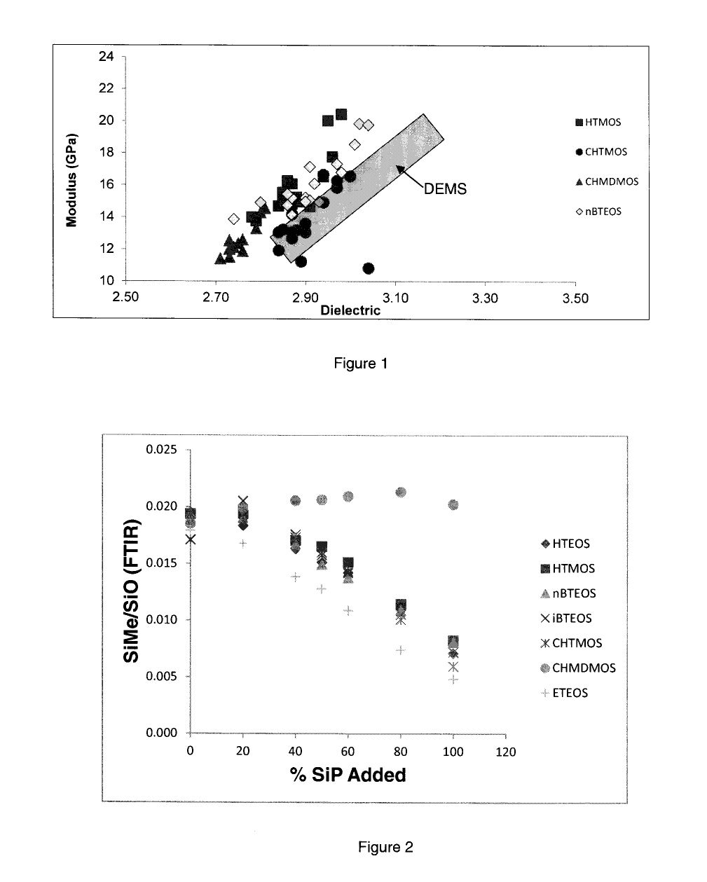

When using a separate porogen precursor such as ATRP in order to lower the dielectric constant of the film, the end user would need to add more porogen into the film. In compositions wherein the structure former precursor comprises DEMS which produces a dense film having a dielectric constant of 3.0, the addition of ATRP allows the dielectric constant to decrease because there is a linear relationship between the added porosity and the dielectric constant. There is also a direct relationship between the maximum film hardness and the dielectric constant, thus as the dielectric constant decreases there is a linear decrease in mechanical properties. There are two ways to shift the k vs. hardness line upward to higher mechanical properties: (a) to increase the mechanical strength of the structure former precursor while maintaining its dielectric constant or (b) to lower the dielectric constant of the structure former precursor while maintaining its mechanical properties. The addition of a porogenated precursor to a composition which also includes the structure former precursor DEMS data allows one to obtain films which after a UV anneal to remove the porogen bonded to silicon (as can be observed by changes in the FTIR spectrum) which have lower dielectric constants yet exhibit the same mechanical properties (see FIG. 1). Therefore, if one needed to add an additional porogen such as ATRP to lower the dielectric constant of a film one could use less of the ATRP in order to achieve the same dielectric constant relative to pure DEMS. Therefore, for certain embodiments, one would need to use less porogen precursor for those compositions that further comprise a structure former precursor and a porogenated precursor. If the films from the porogenated precursor by itself or in mixture with DEMS and the films from pure DEMS have the same base mechanical properties then the film deposited using a composition comprising a porogenated precursor will have higher mechanical properties at the same dielectric constant since less porosity is needed.

Referring again to FIG. 1, the data that shows that for a given composition of film the modulus increases as k increases. If one was to then look at the same data for mixtures of DEMS and porogenated precursor, you can see that this also falls on a line, but the line is shifted to the left, indicating that at the same dielectric constant you get a higher mechanical strength. It is envisioned that if the compositions which comprise DEMS and the porogenated precursor further included an additional porogen precursor, the dielectric constant would be lower (e.g., down to k=0) and if assuming the lines remain parallel then one can achieve higher mechanical strengths at the same k value.

In certain embodiments of the compositions described herein wherein the structure former is one or more porogenated precursors, one can deposit a OSG network with the porogenated precursors alone, unless some of the porogen contained therein is removed as the silicon is incorporated the relative percent porosity upon porogen removal from the as-deposited film will be greater than 50% (e.g., there are only 2.5 atoms in the SiOx network while there are 4-6 carbon atoms in the P) and the films will collapse. It is advantageous in these or other embodiments, therefore, to add additional Si into the network in the form of the structure former DEMS or other silicon precursors to avoid structural collapse.

This is further evidence by XPS elemental composition data on films that are deposited from the structure former DEMS alone and porogenated precursor. A comparison of the carbon levels in the films after UV annealing to remove the porogen contained within is not significantly different than what is seen in films deposited under the same condition using the structure former precursor DEMS alone. Further, FTIR analysis of the same films indicates that the SiMe content in the films decreases with increasing Si—P ratio. Without being bound by theory this indicates that the porogen bonded to the silicon in the porogenated material is breaking at the C—C bond beta to the Silicon resulting in a carbon radical in the Si—CH₂. This raises the possibility that the Si—CH₂ radical may bond back into the OSG network which may result in higher mechanical properties which may explain why one sees lower k values without lower mechanical strength. The SiMe amount as measured by FT-IR gives an indication of the number of terminal bonds present in the material and also indicates that there is more carbon present which lowers the dielectric constant but also lowers the mechanical properties. By contrast, the SiO amount as measured by FT-IR gives an indication of the amount of network bonds present which strengthens the film but also raises the dielectric constant.

Films of the invention have a lower dielectric constant relative to common OSG materials. Preferably, films of the invention have a dielectric constant at least 0.3 less than that of an analogous OSG film produced without porogens, more preferably at least 0.5 less. Preferably, an FTIR spectrum of a porous film of the invention is substantially identical to a reference FTIR of a reference film prepared by a process substantially identical to the method except for a lack of any porogen.

Films of the invention preferably have superior mechanical properties relative to common OSG materials. Preferably, the base OSG structure of the films of the invention (e.g., films that have not had any added porogen) has a hardness or modulus measured by nanoindentation at least 10% greater, more preferably 25% greater, than that of an analogous OSG film at the same dielectric constant.

Films of the invention do not require the use of an oxidant to deposit a low k film. The absence of added oxidant to the gas phase, which is defined for present purposes as a moiety that could oxidize organic groups (e.g., O₂, N₂O, ozone, hydrogen peroxide, NO, NO₂, N₂O₄, or mixtures thereof), facilitates the retention of the methyl groups of the precursor in the film. This allows the incorporation of the minimum amount of carbon necessary to provide desired properties, such as reduced dielectric constant and hydrophobicity. As well, this tends to provide maximum retention of the silica network, providing films that have superior mechanical properties, adhesion, and etch selectivity to common etch stop materials (e.g., silicon carbide, hydrogenated silicon carbide, silicon nitride, hydrogenated silicon nitride, etc.), since the film retains characteristics more similar to silica, the traditional dielectric insulator. However, in alternative embodiments of the method and composition described herein, an additional oxidant can be used during one or more of the method steps.

Films of the invention may also optionally contain fluorine, in the form of inorganic fluorine (e.g., Si—F). Fluorine, when present, is preferably contained in an amount ranging from 0.5 to 7 atomic %.

Films of the invention are thermally stable, with good chemical resistance. In particular, preferred films after anneal have an average weight loss of less than 1.0 wt %/hr isothermal at 425° C. under N₂. Moreover, the films preferably have an average weight loss of less than 1.0 wt %/hr isothermal at 425° C. under air.

The films are suitable for a variety of uses. The films are particularly suitable for deposition on a semiconductor substrate, and are particularly suitable for use as, e.g., an insulation layer, an interlayer dielectric layer and/or an intermetal dielectric layer. The films can form a conformal coating. The mechanical properties exhibited by these films make them particularly suitable for use in Al subtractive technology and Cu damascene or dual damascene technology.

The films are compatible with chemical mechanical planarization (CMP) and anisotropic etching, and are capable of adhering to a variety of materials, such as silicon, SiO₂, Si₃N₄, OSG, fluorosilicon glass (FSG), silicon carbide, hydrogenated silicon carbide, silicon nitride, hydrogenated silicon nitride, silicon carbonitride, hydrogenated silicon carbonitride, boronitride, antireflective coatings, photoresists, organic polymers, porous organic and inorganic materials, metals such as copper and aluminum, and diffusion barrier layers such as but not limited to TiN, Ti(C)N, TaN, Ta(C)N, Ta, W, WN or W(C)N. The films are preferably capable of adhering to at least one of the foregoing materials sufficiently to pass a conventional pull test, such as ASTM D3359-95a tape pull test. A sample is considered to have passed the test if there is no discernible removal of film.

Thus in certain embodiments, the film is an insulation layer, an interlayer dielectric layer, an intermetal dielectric layer, a capping layer, a chemical mechanical planarization or etch stop layer, a barrier layer or an adhesion layer in an integrated circuit.

Although the invention is particularly suitable for providing films and products of the invention are largely described herein as films, the invention is not limited thereto. Products of the invention can be provided in any form capable of being deposited by CVD, such as coatings, multilaminar assemblies, and other types of objects that are not necessarily planar or thin, and a multitude of objects not necessarily used in integrated circuits. Preferably, the substrate is a semiconductor.

In addition to the inventive OSG products, the present invention includes the process by which the products are made, methods of using the products and compounds and compositions useful for preparing the products.

The porogen in the deposited film may or may not be in the same form as the porogens precursor introduced to the reaction chamber. As well, the porogen removal process may liberate the porogen or fragments thereof from the film. In essence, the porogen reagent, the porogen in the preliminary film, and the porogen being removed may or may not be the same species, although it is preferable that they all originate from the porogen reagent. Regardless of whether or not the porogen is unchanged throughout the inventive process, the term “porogen” as used herein is intended to encompass pore-forming reagents and derivatives thereof, in whatever forms they are found throughout the entire process of the invention.

Although the phrase “gaseous reagents” is sometimes used herein to describe the reagents, the phrase is intended to encompass reagents delivered directly as a gas to the reactor, delivered as a vaporized liquid, a sublimed solid and/or transported by an inert carrier gas into the reactor.

In addition, the reagents can be carried into the reactor separately from distinct sources or as a mixture. The reagents can be delivered to the reactor system by any number of means, preferably using a pressurizable stainless steel vessel fitted with the proper valves and fittings to allow the delivery of liquid to the process reactor.

In certain embodiments, mixtures of different organosilanes and/or organosiloxanes are used in combination. It is also within the scope of the invention to use combinations of multiple different porogens and organosilanes. Such embodiments facilitate adjusting the ratio of pores to Si in the final product, and/or enhance one or more critical properties of the base OSG structure. For example, a deposition utilizing diethoxymethylsilane (DEMS) and porogen might use an additional organosilicon such as tetraethoxysilane (TEOS) to improve the film mechanical strength.

As previously mentioned, it is within the scope of the invention for a single species of molecule to function as both the structure-former and porogen. That is, the structure-forming precursor and the pore-forming precursor are not necessarily different molecules, and in certain embodiments the porogen is a part of (e.g., covalently bound to) the structure-forming precursor. Precursors containing porogens bound to them are sometimes referred to hereinafter as “porogenated precursors”. For example, it is possible to use neohexyltriemthoxysialne as a single species, whereby the trimethoxysilane portion of the molecule forms the base OSG structure and the bulky alkyl substituent, cyclohexyl, is the pore forming species which is removed during the anneal process. Having the porogen attached to a Si species that will network into the OSG structure may be advantageous in achieving a higher efficiency of incorporation of porogen into the film during the deposition process. Furthermore, it may also be advantageous to have two porogens attached to one Si in the precursor, such as in di-cyclohexylhexyl-diethoxysilane, or two Si's attached to one porogen, such as in 1,4-bis(diethoxysilyl)cyclohexane, since the most likely bond to break in a plasma during the deposition process is the Si-Porogen bond. In this manner, reaction of one Si-Porogen bond in the plasma will still result in incorporation of the porogen in the deposited film. Additional non-limiting examples of preferred porogenated precursors include octyltriethoxysilane, octyltrimethoxysilane, cyclooctyltriethoxysilane, cyclooctyltrimethoxysilane, octyltrimethoxysialen, octnyltriethoxysilane, hexyltriethoxysilane, isobutyltriethoxysilane, methylcyclohexyldiethoxysilane, cyclooctyltriethoxysilane, butyltriethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane.

In certain embodiments of the materials in which a single or multiple porogen is attached to a silicon, it may be advantageous to design the porogenated precursor with a porogen and a methyl group attached to the silicon so that after the porogen portion is removed the methyl functionality is retained to impart hydrophobicity to the film. Examples of precursors are cyclohexylmethyldimethoxysilane, hexylmethyldimethoxysilane, cyclohexylmethyldiethoxysilane, hexylmethyldiethoxysilane, cyclopentylmethyldiethoxysilane, cyclopentylmethyldimethoxysilane, pentylmethyldiethoxysilane, pentylmethyldimethoxysilane.

In certain embodiments described herein, the porogen bonded to the silicon atom in the porogenated precursor comprises 10 carbon atoms or less such as, without limitation, methyl, ethyl, propyl, isopropyl, butyl, isobutyl, tert-butyl, sec-butyl, pentyl, isoamyl, cyclopentyl, isopentyl, hexyl, cyclohexyl, octyl, and cyclooctyl groups. In this regard, the size of the porogen bonded to the silicon atom allows the precursor to be of sufficient volatility for a PECVD process. Further examples of porogenated precursors include but are not limited to: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof.

The following are non-limiting examples of Si-based structure former precursors. In the chemical formulas which follow and in all chemical formulas throughout this document, the term “independently” should be understood to denote that the subject R group is not only independently selected relative to other R groups bearing different superscripts, but is also independently selected relative to any additional species of the same R group. For example, in the formula R¹ₙ(OR²)₄₋ₙSi, when n is 2 or 3, the two or three R¹ groups need not be identical to each other or to R².
R¹ₙ(OR²)₄₋ₙSi where R¹ can be independently H, C₁ to C₄, linear or branched, saturated, singly or multiply unsaturated, cyclic, partially or fully fluorinated; R² can be independently C₁ to C₆, linear or branched, saturated, singly or multiply unsaturated, cyclic, aromatic, partially or fully fluorinated, n is 1 to 3.
   Example: diethoxymethylsilane, dimethyldimethoxysilane
R¹ₙ(OR²)₃₋ₙSi—O—SiR³ₘ(OR⁴)₃₋ₘ where R¹ and R³ can be independently H, C₁ to C₄, linear or branched, saturated, singly or multiply unsaturated, cyclic, partially or fully fluorinated; R² and R⁴ can be independently C₁ to C₆, linear or branched, saturated, singly or multiply unsaturated, cyclic, aromatic, partially or fully fluorinated, n is 1 to 3 and m is 1 to 3.
   Example: 1,3-dimethyl-1,3-diethoxydisiloxane
R¹ₙ(OR²)₃₋ₙSi—SiR³ₘ(OR⁴)₃₋ₘ where R¹ and R³ can be independently H, C₁ to C₄, linear or branched, saturated, singly or multiply unsaturated, cyclic, partially or fully fluorinated, R² and R⁴ can be independently C₁ to C₆, linear or branched, saturated, singly or multiply unsaturated, cyclic, aromatic, partially or fully fluorinated, n is 1 to 3 and m is 1 to 3.
   Example: 1,2-dimethyl-1,1,2,2-tetraethoxydisilane
R¹ₙ(O(O)CR²)₄₋ₙSi where R¹ can be independently H, C₁ to C₄, linear or branched, saturated, singly or multiply unsaturated, cyclic, partially or fully fluorinated; R² can be independently H, C₁ to C₆, linear or branched, saturated, singly or multiply unsaturated, cyclic, aromatic, partially or fully fluorinated, n is 1 to 3.
   Example: dimethyldiacetoxysilane
R¹ₙ(O(O)CR²)₃₋ₙSi—O—SiR³ₘ(O(O)CR⁴)₃₋ₘ where R¹ and R³ can be independently H, C₁ to C₄, linear or branched, saturated, singly or multiply unsaturated, cyclic, partially or fully fluorinated; R² and R⁴ can be independently H, C₁ to C₆, linear or branched, saturated, singly or multiply unsaturated, cyclic, aromatic, partially or fully fluorinated, n is 1 to 3 and m is 1 to 3.
   Example: 1,3-dimethyl-1,3-diacetoxydisiloxane
R¹ₙ(O(O)CR²)₃₋ₙSi—SiR³ₘ(O(O)CR⁴)₃₋ₘ where R¹ and R³ can be independently H, C₁ to C₄, linear or branched, saturated, singly or multiply unsaturated, cyclic, partially or fully fluorinated; R² and R⁴ can be independently H, C₁ to C₆, linear or branched, saturated, singly or multiply unsaturated, cyclic, aromatic, partially or fully fluorinated, n is 1 to 3 and m is 1 to 3.
   Example: 1,2-dimethyl-1,1,2,2-tetraacetoxydisilane
R¹ₙ(O(O)CR²)₃₋ₙSi—O—SiR³ₘ(OR⁴)₃₋ₘ where R¹ and R³ can be independently H, C₁ to C₄, linear or branched, saturated, singly or multiply unsaturated, cyclic, partially or fully fluorinated; R² can be independently H, C₁ to C₆, linear or branched, saturated, singly or multiply unsaturated, cyclic, aromatic, partially or fully fluorinated, R⁴ can be independently C₁ to C₆, linear or branched, saturated, singly or multiply unsaturated, cyclic, aromatic, partially or fully fluorinated, n is 1 to 3 and m is 1 to 3.
   Example: 1,3-dimethyl-1-acetoxy-3-ethoxydisiloxane
R¹ₙ(O(O)CR²)₃₋ₙSi—SiR³ₘ(OR⁴)₃₋ₘ where R¹ and R³ can be independently H, C₁ to C₄, linear or branched, saturated, singly or multiply unsaturated, cyclic, partially or fully fluorinated; R² can be independently H, C₁ to C₆, linear or branched, saturated, singly or multiply unsaturated, cyclic, aromatic, partially or fully fluorinated and R⁴ can be independently C₁ to C₆, linear or branched, saturated, singly or multiply unsaturated, cyclic, aromatic, partially or fully fluorinated, n is 1 to 3 and m is 1 to 3.
   Example: 1,2-dimethyl-1-acetoxy-2-ethoxydisilane
R¹ₙ(OR²)ₚ(O(O)CR⁴)₄₋₍ₙ₊ₚ₎Si where R¹ can be independently H, C₁ to C₄, linear or branched, saturated, singly or multiply unsaturated, cyclic, partially or fully fluorinated, R² can be independently C₁ to C₆, linear or branched, saturated, singly or multiply unsaturated, cyclic, aromatic, partially or fully fluorinated and R⁴ can be independently H, C₁ to C₆, linear or branched, saturated, singly or multiply unsaturated, cyclic, aromatic, partially or fully fluorinated, and n is 1 to 3 and p is 1 to 3.
   Example: methylacetoxy-t-butoxysilane
R¹ₙ(OR²)ₚ(O(O)CR⁴)₃₋ₙ₋ₚSi—O—SiR³ₘ(O(O)CR⁵)_{q}(OR⁶)_{3-m-q} where R¹ and R³ can be independently H, C₁ to C₄, linear or branched, saturated, singly or multiply unsaturated, cyclic, partially or fully fluorinated; R² and R⁶ can be independently C₁ to C₆, linear or branched, saturated, singly or multiply unsaturated, cyclic, aromatic, partially or fully fluorinated, R⁴ and R⁵ can be independently H, C₁ to C₆, linear or branched, saturated, singly or multiply unsaturated, cyclic, aromatic, partially or fully fluorinated, n is 1 to 3, m is 1 to 3, p is 1 to 3 and q is 1 to 3.
   Example: 1,3-dimethyl-1,3-diacetoxy-1,3-diethoxydisiloxane
R¹ₙ(OR²)ₚ(O(O)CR⁴)₃₋ₙ₋ₚSi—SiR³ₘ(O(O)CR⁵)_{q}(OR⁶)_{3-m-q} where R¹ and R³ can be independently H, C₁ to C₄, linear or branched, saturated, singly or multiply unsaturated, cyclic, partially or fully fluorinated; R², R⁶ can be independently C₁ to C₆, linear or branched, saturated, singly or multiply unsaturated, cyclic, aromatic, partially or fully fluorinated, R⁴, R⁵ can be independently H, C₁ to C₆, linear or branched, saturated, singly or multiply unsaturated, cyclic, aromatic, partially or fully fluorinated, n is 1 to 3, m is 1 to 3, p is 1 to 3 and q is 1 to 3.
   Example: 1,2-dimethyl-1,2-diacetoxy-1,2-diethoxydisilane
cyclic siloxanes of the formula (OSiR₁R₃)ₓ, where R¹ and R³ can be independently H, C₁ to C₄, linear or branched, saturated, singly or multiply unsaturated, cyclic, partially or fully fluorinated, and x may be any integer from 2 to 8.

Examples: 1,3,5,7-tetramethylcyclotetrasiloxane, octamethylcyclotetrasiloxane

The above precursors may be mixed with porogen or have attached porogens (e.g., porogenated precursors), and may be mixed with other molecules of these classes and/or with molecules of the same classes except where n and/or m are from 0 to 3.
Examples: TEOS, triethoxysilane, di-tertiarybutoxysilane, silane, disilane, di-tertiarybutoxydiacetoxysilane, etc.

The following are additional formulas representing certain Si-based structure former precursors suitable for the method or compositions described herein:

(a) the formula R¹ₙ(OR²)ₚ(O(O)CR³)₄₋₍ₙ₊ₚ₎Si where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3 and p is 0 to 3;

(b) the formula R¹ₙ(OR²)ₚ(O(O)CR⁴)₃₋ₙ₋ₚSi—O—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R² and R⁶ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3 and m+q≦3;

(c) the formula R¹ₙ(OR²)ₚ(O(O)CR⁴)₃₋ₙ₋ₚSi—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R² and R⁶ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3 and m+q≦3;

(d) the formula R¹ₙ(OR²)ₚ(O(O)CR⁴)₃₋ₙ₋ₚSi—R⁷—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R², R⁶ and R⁷ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3, and m+q≦3;

(e) the formula (R¹ₙ(OR²)ₚ(O(O)CR³)₄₋₍ₙ₊ₚ₎Si)ₜCH₄₋ₜ where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3, p is 0 to 3, and t is 2 to 4, provided that n+p≦4;

(f) the formula (R¹ₙ(OR²)ₚ(O(O)CR³)₄₋₍ₙ₊ₚ₎Si)ₜNH₃₋ₜ where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3, p is 0 to 3 and t is 1 to 3, provided that n+p≦4;

(g) cyclic siloxanes of the formula (OSiR₁R₃)ₓ, where R¹ and R³ are independently H, C₁ to C₄, linear or branched, saturated, singly or multiply unsaturated, cyclic, partially or fully fluorinated, and x may be any integer from 2 to 8;

(h) cyclic silazanes of the formula (NR₁SiR₁R₃)ₓ, where R¹ and R³ are independently H, C₁ to C₄, linear or branched, saturated, singly or multiply unsaturated, cyclic, partially or fully fluorinated, and x may be any integer from 2 to 8; and

(i) cyclic carbosilanes of the formula (CR₁R₃SiR₁R₃)ₓ, where R¹ and R³ are independently H, C₁ to C₄, linear or branched, saturated, singly or multiply unsaturated, cyclic, partially or fully fluorinated, and x may be any integer from 2 to 8.

Although reference is made throughout the specification to siloxanes and disiloxanes as precursors and porogenated precursors, it should be understood that the invention is not limited thereto, and that other siloxanes, such as trisiloxanes and other linear siloxanes of even greater length, are also within the scope of the invention.

The following are non-limiting examples of porogenated precursors, where the porogen material is one or more of R¹, R³ or R⁷:
R¹ₙ(OR²)₃₋ₙSi where R¹ can be independently H, C₁ to C₁₂, linear or branched, saturated, singly or multiply unsaturated, cyclic, partially or fully fluorinated; R² can be independently C₁ to C₁₂, linear or branched, saturated, singly or multiply unsaturated, cyclic, aromatic, partially or fully fluorinated, n is 1 to 3.
   Example: diethoxy-neo-hexylsilane
R¹ₙ(OR²)₃₋ₙSi—O—SiR³ₘ(OR⁴)₃₋ₘ where R¹ and R³ can be independently H, C₁ to C₁₂, linear or branched, saturated, singly or multiply unsaturated, cyclic, partially or fully fluorinated; R² and R⁴ can be independently C₁ to C₁₂, linear or branched, saturated, singly or multiply unsaturated, cyclic, aromatic, partially or fully fluorinated, n is 1 to 3 and m is 1 to 3.
   Example: 1,3-diethoxy-1-neo-hexyldisiloxane
R¹ₙ(OR²)₃₋ₙSi—SiR³ₘ(OR⁴)₃₋ₘ where R¹ and R³ can be independently H, C₁ to C₁₂, linear or branched, saturated, singly or multiply unsaturated, cyclic, partially or fully fluorinated, R² and R⁴ can be independently C₁ to C₁₂, linear or branched, saturated, singly or multiply unsaturated, cyclic, aromatic, partially or fully fluorinated, n is 1 to 3 and m is 1 to 3.
   Example: 1,2-diethoxy-1-neo-hexyldisilane
R¹ₙ(OR²)₃₋ₙSi—R⁷—SiR³ₘ(OR⁴)₃₋ₘ where R¹ and R³ can be independently H, C₁ to C₁₂, linear or branched, saturated, singly or multiply unsaturated, cyclic, partially or fully fluorinated, R² and R⁴ can be independently C₁ to C₁₂, linear or branched, saturated, singly or multiply unsaturated, cyclic, aromatic, partially or fully fluorinated, R⁷ is C₁ to C₁₂, linear or branched, saturated, singly or multiply unsaturated, cyclic, partially or fully fluorinated, and bridges the two Si atoms, n is 1 to 3 and m is 1 to 3.
   Example: 1,4-bis(dimethoxysilyl)cyclohexane
R¹ₙ(OR²)₃₋ₙSi—SiR³ₘ(OR⁴)₃₋ₘ where R¹ and R³ can be independently H, C₁ to C₁₂, linear or branched, saturated, singly or multiply unsaturated, cyclic, partially or fully fluorinated, R² and R⁴ can be independently C₁ to C₁₂, linear or branched, saturated, singly or multiply unsaturated, cyclic, aromatic, partially or fully fluorinated, n is 1 to 3 and m is 1 to 3.
   Example: 1,2-diethoxy-1-neo-hexyldisilane
R¹ₙ(O(O)CR²)₄₋ₙSi where R¹ can be independently H, C₁ to C₁₂, linear or branched, saturated, singly or multiply unsaturated, cyclic, partially or fully fluorinated; R² can be independently H, C₁ to C₁₂, linear or branched, saturated, singly or multiply unsaturated, cyclic, aromatic, partially or fully fluorinated, n is 1 to 3.
   Example: diacetoxy-neo-hexylsilane
R¹ₙ(O(O)CR²)₃₋ₙSi—O—SiR³ₘ(O(O)CR⁴)₃₋ₘ where R¹ and R³ can be independently H, C₁ to C₁₂, linear or branched, saturated, singly or multiply unsaturated, cyclic, partially or fully fluorinated; R² and R⁴ can be independently H, C₁ to C₁₂, linear or branched, saturated, singly or multiply unsaturated, cyclic, aromatic, partially or fully fluorinated, n is 1 to 3 and m is 1 to 3.
   Example: 1,3-diacetoxy-1-neo-hexyldisiloxane
R¹ₙ(O(O)CR²)₃₋ₙSi—SiR³ₘ(O(O)CR⁴)₃₋ₘ where R¹ and R³ can be independently H, C₁ to C₁₂, linear or branched, saturated, singly or multiply unsaturated, cyclic, partially or fully fluorinated; R² and R⁴ can be independently H, C₁ to C₁₂, linear or branched, saturated, singly or multiply unsaturated, cyclic, aromatic, partially or fully fluorinated, n is 1 to 3 and m is 1 to 3.
   Example: 1,2-diacetoxy-1-neo-hexyldisilane
R¹ₙ(O(O)CR²)₃₋ₙSi—O—SiR³ₘ(OR⁴)₃₋ₘ where R¹ and R³ can be independently H, C₁ to C₁₂, linear or branched, saturated, singly or multiply unsaturated, cyclic, partially or fully fluorinated; R² can be independently H, C₁ to C₁₂, linear or branched, saturated, singly or multiply unsaturated, cyclic, aromatic, partially or fully fluorinated, R⁴ can be independently C₁ to C₁₂, linear or branched, saturated, singly or multiply unsaturated, cyclic, aromatic, partially or fully fluorinated, n is 1 to 3 and m is 1 to 3.
   Example: 1-acetoxy-3,3-di-t-butoxy-1-neohexyldisiloxane
R¹ₙ(O(O)CR²)₃₋ₙSi—SiR³ₘ(OR⁴)₃₋ₘ where R¹ and R³ can be independently H, C₁ to C₁₂, linear or branched, saturated, singly or multiply unsaturated, cyclic, partially or fully fluorinated; R² can be independently H, C₁ to C₁₂, linear or branched, saturated, singly or multiply unsaturated, cyclic, aromatic, partially or fully fluorinated, R⁴ can be independently C₁ to C₁₂, linear or branched, saturated, singly or multiply unsaturated, cyclic, aromatic, partially or fully fluorinated, n is 1 to 3 and m is 1 to 3.
   Example: 1-acetoxy-2,2-di-t-butoxy-1-neohexyldisilane
R¹ₙ(OR²)ₚ(O(O)CR³)₄₋₍ₙ₊ₚ₎Si where R¹ can be independently H, C₁ to C₁₂, linear or branched, saturated, singly or multiply unsaturated, cyclic, partially or fully fluorinated, R² can be independently C₁ to C₁₂, linear or branched, saturated, singly or multiply unsaturated, cyclic, aromatic, partially or fully fluorinated; R³ can be independently H, C₁ to C₁₂, linear or branched, saturated, singly or multiply unsaturated, cyclic, aromatic, partially or fully fluorinated, and n is 1 to 3 and p is 1 to 3.
   Example: acetoxy-t-butoxy-neo-hexylsilane
R¹ₙ(OR²)ₚ(O(O)CR⁴)₃₋ₙ₋ₚSi—O—SiR³ₘ(O(O)CR⁶)_{q}(OR⁶)_{3-m-q} where R¹ and R³ can be independently H, C₁ to C₁₂, linear or branched, saturated, singly or multiply unsaturated, cyclic, partially or fully fluorinated; R², R⁶ can be independently C₁ to C₁₂, linear or branched, saturated, singly or multiply unsaturated, cyclic, aromatic, partially or fully fluorinated, R⁴, R⁵ can be independently H, C₁ to C₁₂, linear or branched, saturated, singly or multiply unsaturated, cyclic, aromatic, partially or fully fluorinated, n is 1 to 3, m is 1 to 3, p is 1 to 3 and q is 1 to 3.
   Example: 1,3-diacetoxy-1,3-di-t-butoxy-1-neohexyldisiloxane
R¹ₙ(OR²)ₚ(O(O)CR⁴)₃₋ₙ₋ₚSi−SiR³ₘ(O(O)CR⁵)_{q}(OR⁶)_{3-m-q} where R¹ and R³ can be independently H, C₁ to C₁₂, linear or branched, saturated, singly or multiply unsaturated, cyclic, partially or fully fluorinated; R², R⁶ can be independently C₁ to C₁₂, linear or branched, saturated, singly or multiply unsaturated, cyclic, aromatic, partially or fully fluorinated, R⁴, R⁵ can be independently H, C₁ to C₁₂, linear or branched, saturated, singly or multiply unsaturated, cyclic, aromatic, partially or fully fluorinated, n is 1 to 3, m is 1 to 3, p is 1 to 3 and q is 1 to 3.
   Example: 1,2-diacetoxy-1,2-di-t-butoxy-1-neohexyldisilane
cyclic siloxanes of the formula (OSiR₁R₃)x, where R¹ and R³ can be independently H, C₁ to C₁₂, linear or branched, saturated, singly or multiply unsaturated, cyclic, partially or fully fluorinated, and x may be any integer from 2 to 8.
   Example: such as 1-neohexyl-1,3,5,7-tetramethylcyclotetrasiloxane

The above porogenated precursors may be mixed with other molecules of these same classes and/or with molecules of the same classes except where n and/or m are from 0 to 3.

The following are non-limiting examples of porogen precursors to be used in the composition or methods described herein:

1) Cyclic hydrocarbons of the general formula CₙH₂ₙ where n=4-14, where the number of carbons in the cyclic structure is between 4 and 10, and where there can be a plurality of simple or branched hydrocarbons substituted onto the cyclic structure.

Examples include: cyclohexane, trimethylcyclohexane, 1-methyl-4(1-methylethyl)cyclohexane, cyclooctane, methylcyclooctane, etc.

2) Linear or branched, saturated, singly or multiply unsaturated hydrocarbons of the general formula CₙH_{(2b+2)-2y} where n=2-20 and where y=0−n.

Examples include: ethylene, propylene, acetylene, neohexane, etc.

3) Singly or multiply unsaturated cyclic hydrocarbons of the general formula CₙH₂ₙ₋₂ₓ where x is the number of unsaturated sites in the molecule, n=4-14, where the number of carbons in the cyclic structure is between 4 and 10, and where there can be a plurality of simple or branched hydrocarbons substituted onto the cyclic structure. The unsaturation can be located inside endocyclic or on one of the hydrocarbon substituents to the cyclic structure.
cyclohexene, vinylcyclohexane, dimethylcyclohexene,
t-butylcyclohexene, alpha-terpinene, bicycloheptadiene (BCHD), pinene, 1,5-dimethyl-1,5-cyclooctadiene, 1,5-cyclooctadiene, vinyl-cyclohexene, etc.

4) Bicyclic hydrocarbons of the general formula CₙH₂ₙ₋₂ where n=4-14, where the number of carbons in the bicyclic structure is between 4 and 12, and where there can be a plurality of simple or branched hydrocarbons substituted onto the cyclic structure.

Examples include, norbornane, spiro-nonane, decahydronaphthalene, etc.

5) Multiply unsaturated bicyclic hydrocarbons of the general formula CₙH₂ₙ₋₍₂₊₂ₓ₎ where x is the number of unsaturated sites in the molecule, n=4-14, where the number of carbons in the bicyclic structure is between 4 and 12, and where there can be a plurality of simple or branched hydrocarbons substituted onto the cyclic structure. The unsaturation can be located inside endocyclic or on one of the hydrocarbon substituents to the cyclic structure.

Examples include camphene, norbornene, norbornadiene, etc.

6) Tricyclic hydrocarbons of the general formula CₙH₂ₙ₋₄ where n=4-14, where the number of carbons in the tricyclic structure is between 4 and 12, and where there can be a plurality of simple or branched hydrocarbons substituted onto the cyclic structure.

Examples include adamantane.

In addition to the structure forming precursors, porogen precursors, and porogen precursors described herein, additional materials can be charged into the vacuum chamber prior to, during and/or after the deposition reaction. Such materials include, e.g., inert gas (e.g., He, Ar, N₂, Kr, Xe, etc., which may be employed as a carrier gas for lesser volatile precursors and/or which can promote the curing of the as-deposited materials and provide a more stable final film) and reactive substances, such as gaseous or liquid organic substances, NH₃, H₂, CO₂, or CO. CO₂ is the preferred carrier gas. Oxidizing gases such as, for example, O₂, N₂O, NO, NO₂ and O₃ may also be added.

Energy is applied to the gaseous reagents to induce the gases to react and to form the film on the substrate. Such energy can be provided by, e.g., thermal, plasma, pulsed plasma, helicon plasma, high density plasma, inductively coupled plasma, and remote plasma methods. A secondary radio frequency (rf) frequency source can be used to modify the plasma characteristics at the substrate surface. Preferably, the film is formed by plasma enhanced chemical vapor deposition. It is particularly preferred to generate a capacitively coupled plasma at a frequency of 13.56 MHz. Plasma power is preferably from 0.02 to 7 watts/cm², more preferably 0.3 to 3 watts/cm², based upon a surface area of the substrate. It may be advantageous to employ a carrier gas which possesses a low ionization energy to lower the electron temperature in the plasma which in turn will cause less fragmentation in the OSG precursor and porogen. Examples of this type of low ionization gas include CO₂, NH₃, CO, CH₄, Ar, Xe, and Kr.

The flow rate for each of the gaseous reagents preferably ranges from 10 to 5000 sccm, more preferably from 30 to 1000 sccm, per single 200 mm wafer. The individual rates are selected so as to provide the desired amounts of structure-former and pore-former in the film. The actual flow rates needed may depend upon wafer size and chamber configuration, and are in no way limited to 200 mm wafers or single wafer chambers.

It is preferred to deposit the film at a deposition rate of at least 50 nm/min.

The pressure in the vacuum chamber during deposition is preferably 0.01 to 600 torr, more preferably 1 to 15 torr.

The film is preferably deposited to a thickness of 0.002 to 10 microns, although the thickness can be varied as required. The blanket film deposited on a non-patterned surface has excellent uniformity, with a variation in thickness of less than 2% over 1 standard deviation across the substrate with a reasonable edge exclusion, wherein e.g., a 5 mm outermost edge of the substrate is not included in the statistical calculation of uniformity.

The porosity of the film can be increased with the bulk density being correspondingly decreased to cause further reduction in the dielectric constant of the material and extending the applicability of this material to future generations (e.g., k<2.0).

The invention further provides compositions to be employed according to the claimed methods of the present invention. A composition according to the present invention preferably comprises: (a)(i) a porogenated precursor selected from the group consisting of: octyltriethoxysilane, octyltrimethoxysilane, cyclooctyltriethoxysilane, cyclooctyltrimethoxysilane, octyltrimethoxysialen, octyltriethoxysilane, hexyltriethoxysilane, isobutyltriethoxysilane, methylcyclohexyldiethoxysilane, cyclooctyltriethoxysilane, butyltriethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; (a)(ii) a structure former precursor selected from the group consisting of diethoxymethylsilane, dimethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trimethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof; and (b) a porogen precursor selected from the group consisting of: alpha-terpinene, bicycloheptadiene (BCHD), limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, 1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes and decahydronaphthele.

In a further aspect, the present invention provides a composition for depositing porous low dielectric constant film comprising: (a)(i) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and (a)(ii) a structure former precursor selected from the group consisting of diethoxymethylsilane, dim ethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trim ethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof. In this or other embodiments, the composition further comprises a porogen precursor.

In still another aspect, the present invention provides a composition for depositing porous low dielectric constant film comprising: (a) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilylethyl)cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and (b) a porogen precursor selected from the group consisting of: alpha-terpinene, limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes, bicycloheptadiene (BCHD), and decahydronaphthele. In this or other embodiments, the composition further comprises a structure former precursor.

Compositions of the invention can further comprise, e.g., at least one pressurizable vessel (preferably of stainless steel) fitted with the proper valves and fittings to allow the delivery of porogen, structure former precursor, porogenated precursor to the process reactor. In certain embodiments, the contents of the vessel(s) can be premixed. Alternatively, porogen and precursor can be maintained in separate vessels or in a single vessel having separation means for maintaining the porogen and precursor separate during storage. Such vessels can also have means for mixing the porogen and precursor when desired.

The porogen is fully or partially removed from the preliminary (or as-deposited) film by a curing step, which can comprise thermal annealing, exposure to ultraviolet radiation, chemical treatment, in-situ or remote plasma treating, photocuring and/or microwaving. Other in-situ or post-deposition treatments may be used to enhance materials properties like hardness, stability (to shrinkage, to air exposure, to etching, to wet etching, etc.), integrity, uniformity and adhesion. Such treatments can be applied to the film prior to, during and/or after porogen removal using the same or different means used for porogen removal. Thus, the term “post-treating” as used herein denotes treating the film with energy (e.g., thermal, plasma, photon, electron, microwave, etc.) or chemicals to remove porogens and, optionally, to enhance materials properties.

The conditions under which post-treating are conducted can vary greatly. For example, post-treating can be conducted under high pressure or under a vacuum ambient.

Annealing is conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.) or reducing (dilute or concentrated hydrogen, hydrocarbons (saturated, unsaturated, linear or branched, aromatics), etc.). The pressure is preferably about 1 Torr to about 1000 Torr, more preferably atmospheric pressure. However, a vacuum ambient is also possible for thermal annealing as well as any other post-treating means. The temperature is preferably 200-500° C., and the temperature ramp rate is from 0.1 to 100 deg ° C./min. The total annealing time is preferably from 0.01 min to 12 hours.

Chemical treatment of the OSG film is conducted under the following conditions.

The use of fluorinating (HF, SIF₄, NF₃, F₂, COF₂, CO₂F₂ etc.), oxidizing (H₂O₂, O₃, etc.), chemical drying, methylating, or other chemical treatments that enhance the properties of the final material. Chemicals used in such treatments can be in solid, liquid, gaseous and/or supercritical fluid states.

Supercritical fluid post-treatment for selective removal of porogens from an organosilicate film is conducted under the following conditions.

The fluid can be carbon dioxide, water, nitrous oxide, ethylene, SF₆, and/or other types of chemicals. Other chemicals can be added to the supercritical fluid to enhance the process. The chemicals can be inert (e.g., nitrogen, CO₂, noble gases (He, Ar, Ne, Kr, Xe), etc.), oxidizing (e.g., oxygen, ozone, nitrous oxide, etc.), or reducing (e.g., dilute or concentrated hydrocarbons, hydrogen, etc.). The temperature is preferably ambient to 500° C. The chemicals can also include larger chemical species such as surfactants. The total exposure time is preferably from 0.01 min to 12 hours.

Plasma treating for selective removal of labile groups and possible chemical modification of the OSG film is conducted under the following conditions.

The environment can be inert (nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.), or reducing (e.g., dilute or concentrated hydrogen, hydrocarbons (saturated, unsaturated, linear or branched, aromatics), etc.). The plasma power is preferably 0-5000 W. The temperature is preferably ambient to 500° C. The pressure is preferably 10 mtorr to atmospheric pressure. The total curing time is preferably 0.01 min to 12 hours.

Photocuring or UV exposure is conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.), or reducing (e.g., dilute or concentrated hydrocarbons, hydrogen, etc.). The temperature is preferably ambient to 500° C. The power is preferably 0 to 5000 W. The wavelength is preferably IR, visible, UV or deep UV (wavelengths <200 nm). The total curing time is preferably 0.01 min to 12 hours.

Microwave post-treatment for selective removal of porogens from an organosilicate film is conducted under the following conditions.

The environment can be inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.), or reducing (e.g., dilute or concentrated hydrocarbons, hydrogen, etc.). The temperature is preferably ambient to 500° C. The power and wavelengths are varied and tunable to specific bonds. The total curing time is preferably from 0.01 min to 12 hours.

Electron beam post-treatment for selective removal of porogens or specific chemical species from an organosilicate film and/or improvement of film properties is conducted under the following conditions.

The environment can be vacuum, inert (e.g., nitrogen, CO₂, noble gases (He, Ar, Ne, Kr, Xe), etc.), oxidizing (e.g., oxygen, air, dilute oxygen environments, enriched oxygen environments, ozone, nitrous oxide, etc.), or reducing (e.g., dilute or concentrated hydrocarbons, hydrogen, etc.). The temperature is preferably ambient to 500° C. The electron density and energy can be varied and tunable to specific bonds. The total curing time is preferably from 0.001 min to 12 hours, and may be continuous or pulsed. Additional guidance regarding the general use of electron beams is available in publications such as: S. Chattopadhyay et al., Journal of Materials Science, 36 (2001) 4323-4330; G. Kloster et al., Proceedings of IITC, Jun. 3-5, 2002, SF, CA; and U.S. Pat. Nos. 6,207,555 B1, 6,204,201 B1 and 6,132,814 A1. The use of electron beam treatment may provide for porogen removal and enhancement of film mechanical properties through bond-formation processes in matrix.

The invention will be illustrated in more detail with reference to the following Examples, but it should be understood that the present invention is not deemed to be limited thereto.

### EXAMPLES

All experiments were performed on an Applied Materials Precision-5000 PECVD system in a 200 mm DxZ chamber fitted with direct liquid injection delivery capability. The recipe involved the following basic steps: initial set-up and stabilization of gas flows, deposition, and purge/evacuation of chamber prior to wafer removal. Typical total liquid precursor flow rates were 800-1500 mg/min, and typical plasma power density was 600-650 W, pressure was 7 torr, and temperature was 250° C. Films were annealed using UV cure for a time of less than 10 minutes to remove the porogen contained therein.

Thickness and refractive index at 632 nm were measured by an SCl reflectometer. Typical film thickness for all above analysis was 400-600 nm. An MDC Hg probe was utilized to determine the dielectric constant. Bonding properties of the dielectric films were analyzed with a Nicolet transmission FTIR spectrometer. Carbon composition was determined using x-ray photoelectron spectroscopy (XPS). The atomic % values reported in the tables do not include hydrogen. An Agilent G200 nanoindentor was used to measure elastic modulus and hardness values in the CSM (continuous stiffness measurement) mode. Finally, porosity measurements were made using both ellipsometry porosimitry (EP) and positron annihilation lifetime spectroscopy (PALS). EP was done using a Sopra EP-12 system and was used primarily to determine the percentage of the film that is porous as well as estimate an average micropore size. Diffusivity of toluene was also collected in the Sopra EP-12 system. PALS data was utilized to determine the interconnection length as well as a more rigorous pore size distribution. Although a number of methods have been introduced in measuring the porosity and pore size distribution of thin film OSGs, it seems that PALS and EP have been embraced as complementary methods to characterize porosity and pore size. PALS is particularly useful in determining the pore size distribution and interconnection length. Because the size of the positron probe used in PALS is considerably smaller than probes used for other porosimetry measurements, they are able to access closed pores, which will not be accessible by EP. On the other hand, EP has been recognized as a simple method to determine the total volume porosity of OSG films, with the dependence of the porosity simply related to the measurement of the film's refractive index. Pore size information can also be determined by EP, although only open pores can be measured and adsorption/desorption isotherms are valuable in broadly deducing pore characteristics.

### Example 1

### Films Deposited Using Structure Former Alone, Porogenated Precursor Alone, or Combinations Thereof

The present examples compare depositions of various porogenated precursors alone or in various weight ratios either as a one-precursor composition or in conjunction with an industrially accepted low k structure former precursor such as DEMS®. A series of PECVD films were deposited with porogenated precursors alone (100% porogenated precursor) or porogenated precursors mixed with DEMS® in different ratios. These films were subject to a short UV treatment designed to remove the bulky organic groups. The results of these depositions are provided herein in the following Tables 1 through 3 and FIG. 2 through 4.

TABLE 1
Comparison of Films Deposited from Compositions having Different Ratios of
Porogenated Precursor and DEMS and SiMe/SiO ratio (as obtained by FT-IR)

| | SiMe/SiO | | | | | | |
|---|---|---|---|---|---|---|---|
| % additive | HTEOS | HTMOS | nBTEOS | iBTEOS | CHTMOS | CHMDMOS | ETEOS |
| 0 | 0.020 | 0.019 | 0.019 | 0.017 | 0.019 | 0.019 | 0.018 |
| 20 | 0.018 | 0.019 | 0.019 | 0.021 | 0.019 | 0.020 | 0.017 |
| 40 | 0.016 | 0.017 | 0.017 | 0.018 | 0.017 | 0.021 | 0.014 |
| 50 | 0.015 | 0.017 | 0.015 | 0.016 | 0.016 | 0.021 | 0.013 |
| 60 | 0.014 | 0.015 | 0.014 | 0.014 | 0.014 | 0.021 | 0.011 |
| 80 | 0.011 | 0.011 | 0.011 | 0.011 | 0.010 | 0.021 | 0.007 |
| 100 | 0.007 | 0.008 | 0.008 | 0.007 | 0.006 | 0.020 | 0.005 |

TABLE 2
Comparison of Films Deposited from Compositions having Different Ratios of
Porogenated Precursor and DEMS and the Decrease in CHx (as measured by FT-IR)

| % additive | HTEOS | HTMOS | nBTEOS | iBTEOS | CHTMOS | CHMDMOS | ETEOS |
|---|---|---|---|---|---|---|---|
| 100 | 3.55 | 3.27133 | 2.7576 | 2.2496 | 3.583 | 3.2242 | 1.9987 |
| 80 | 2.92 | 2.82999 | 2.4069 | 1.8562 | 3.2713 | 2.8033 | 1.7823 |
| 60 | 2.15 | 2.1831 | 1.8446 | 1.4241 | 2.6869 | 2.3941 | 1.5123 |
| 50 | 1.88 | 1.9777 | 1.5963 | | 2.3464 | 2.219 | 1.3665 |
| 40 | 1.64 | 1.7106 | 1.5177 | 1.1499 | 2.073 | 2.0057 | 1.2976 |
| 20 | 1.14 | 1.2204 | 1.137 | 0.9164 | 1.4037 | 1.621 | 1.0123 |
| 0 | 0.91 | 0.9324 | 0.9145 | 0.793 | 0.9913 | 1.2939 | 0.8817 |

TABLE 3
Properties of Films Deposited using 100% Porogenated Precursor

| | | | | | | Avg pore |
|---|---|---|---|---|---|---|
| | | M | | % | Porosity | diameter |
| Film | k | (GPa) | C at % | Shrinkage | (%) | (A) |
| ETEOS | 3.05 | 17.41 | 12.2 | 13.1 | n/a | n/a |
| nBTEOS | 2.74 | 13.87 | 12.8 | 14 | 20.7 | 8.4 |
| iBTEOS | 2.89 | 12.9 | 11.3 | 19.6 | 12.3 | 7.7 |
| HTEOS | 2.6 | 11.36 | 11.4 | 21.3 | n/a | n/a |
| HTMOS | 2.79 | 13.77 | 15.7 | 21.7 | 14.3 | 9.1 |
| CHTMOS | 3.04 | 10.83 | 17.2 | 21.8 | 15.9 | 5.8 |
| CHMDMOS | 2.65 | 9.67 | 25.2 | 20.8 | 11.5 | 7.3 |
| DEMS | 2.94 | 15.79 | 18.6 | 10.6 | — | — |

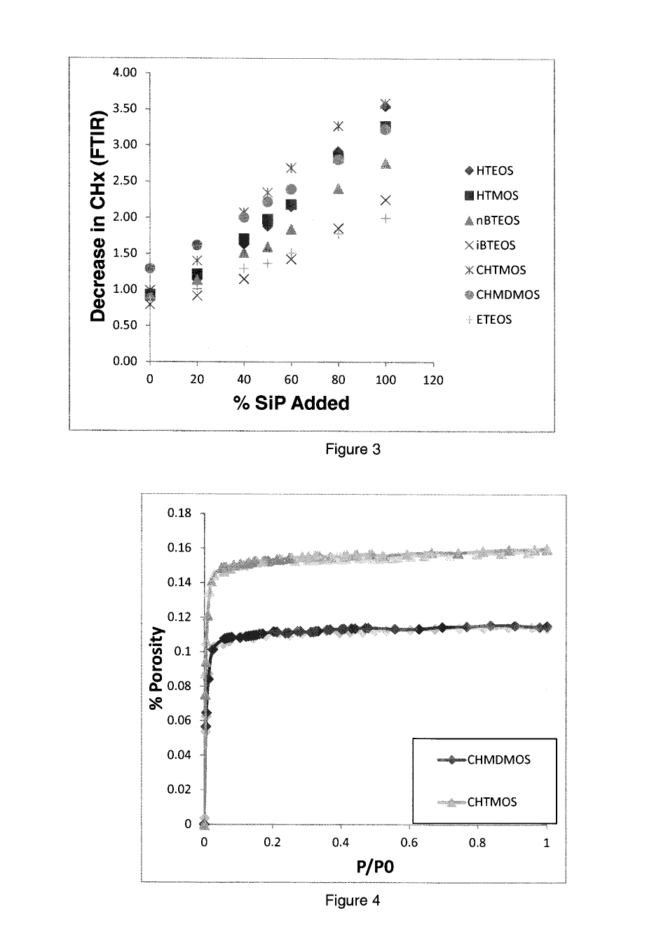

The loss of labile organic content after UV cure was measured as a change in CHx content before and after UV treatment as determined by FTIR. This decrease is related to the extent of porosity formation in the film. For a pure DEMS-based OSG film (0% porogenated precursors), this change is mainly related to a loss of —CH₃ groups. As seen in FIG. 2, different porogenated precursors impart differing levels of organic content into the film, suggesting the ability to tailor and control the porosity by choice of appropriate precursors. The open porosity in these films ranged from non-measurable (e.g. for pure DEMS film) to about 20%. The effects of successively adding more porogenated precursor to DEMS in the compositions also shows very linear behavior in the decrease of the CHx, suggesting good ability to control the amount of porosity (see FIG. 3). The average pore diameter (measured by toluene EP) for the 100% porogenated precursor films was typically <1 nm (see FIG. 4), indicating that the pore size can be decreased by using these alternative precursors with bulky organic groups.

### Example 2

### Films Deposited Using Porogenated Precursor Alone, Porogen Precursors, or Combinations Thereof

The porogenated precursors used herein were chosen to be compatible with current microelectronic processing limitations for delivery of precursors. The lowest k value obtained with this screening scheme was 2.6, necessitating the addition of further porosity to lower the k value to 2.2-2.0 levels. While porogenated precursors with bulkier groups are available (e.g., having carbon atoms greater than 6), their high molecular weights and boiling points hinder their ability to be vaporized and delivered to the chamber easily. Furthermore, films produced with porogenated precursors containing large bulky groups tend to show higher film shrinkages, which may be a challenge for high volume manufacturing. For OSG films deposited with porogenated precursors, bond breakage in the film is necessary to remove the labile group or porogen. The dangling silicon bond then attempts to form an Si—O—Si network upon UV exposure, thus necessitating film shrinkage. In contrast, when a separate porogen precursor such as alpha-terpinene (ATRP) is used, the porogen tends to agglomerate into clusters and form an organic phase, and the OSG network is built around this phase. Hence less shrinkage is expected upon UV exposure when separate structure formers and porogens are used.

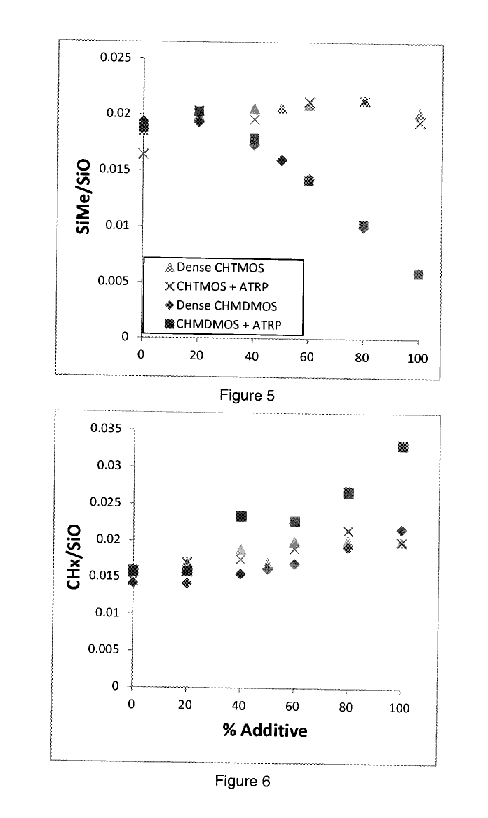

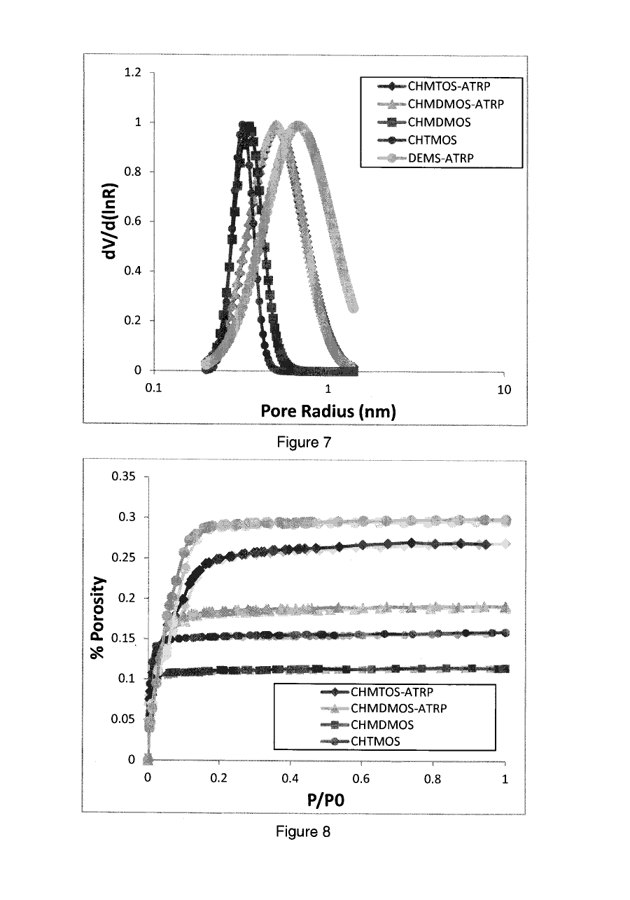

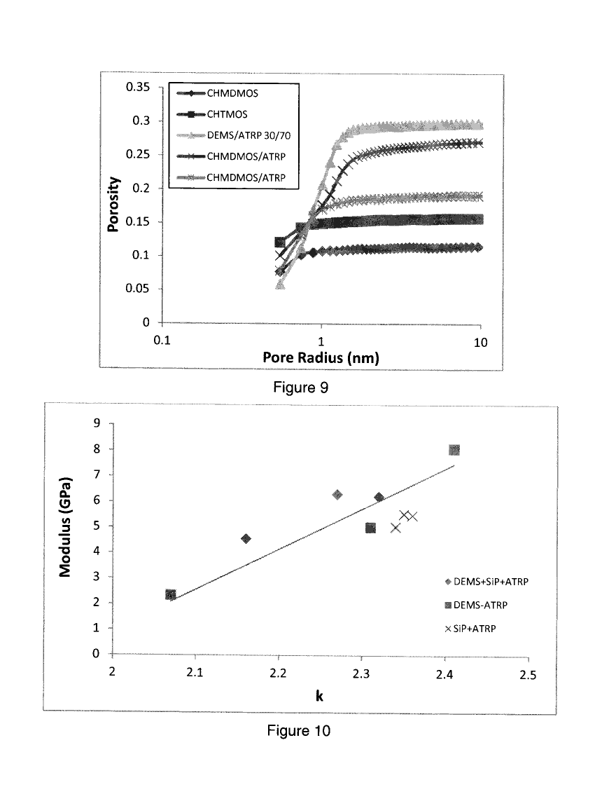

Due to the two limitations discussed above (HVM compatibility and film shrinkage), bulkier porogenated precursors were not considered. Instead, attempts were made to further lower the k value by using the ASFs in conjunction with a distinct porogen precursor, namely ATRP. A potential challenge with this approach is the possibility of agglomeration of the small pores from the porogenated precursors labile groups with the pores created from the distinct porogen precursor, leading to a larger pore size distribution and/or a larger average pore diameter. CHMTOS and CHMDMOS had a large impact in FIG. 3, and they were chosen to test this hypothesis. Table 4 shows the summary of the resulting films which were deposited using CHMTOS and CHMDMOS alone (e.g., 100% porogenated precursor), CHMTOS and CHMDMOS in a 30/70 weight percentage mix ratio with ATRP, and as a comparison DEMS/ATRP in a 30/70 weight percentage mix ratio. FIG. 5 through FIG. 9 provide additional comparative analysis.

TABLE 4
Comparison of Various Film Compositions Comprising Porogenated
Precursor and ATRP

| | | | | | % | Po- | Avg pore |
|---|---|---|---|---|---|---|---|
| | | | M | C | shrink- | rosity | diameter |
| | Film | K | (GPa) | at % | age | (%) | (nm) |
| 30/70 | DEMS/ATRP | 2.41 | 8.09 | 18 | 22.7 | 29.8 | 12.7 |
| | CHTMOS | 3.04 | 10.83 | 17.2 | 21.7 | 15.9 | 5.8 |
| 30/70 | CHTMOS/ | 2.35 | 5.53 | 29 | 36.6 | 26.9 | 9.6 |
| | ATRP | | | | | | |
| | CHMDMOS | 2.65 | 9.67 | 25.2 | 20.8 | 11.5 | 7.3 |
| 30/70 | CHMDMOS/ | 2.36 | 5.48 | 31.2 | 40.7 | 19.1 | 10.2 |
| | ATRP | | | | | | |

IR comparative data shows that the addition of ATRP does not alter the film structure significantly compared to compositions comprising the porogenated precursor alone. In terms of porosity, the films comprising the porogenated precursors and ATRP did show a slight increase in average pore size compared to the ASF films alone (<1 nm). This is also evident from the toluene EP uptake behavior shown in FIG. 8. For compositions comprising CHMDMOS, a sharp uptake is seen at very low partial pressures (<0.07 P/P₀), indicating that the film has a tight pore size distribution and that the pores are very small. Generally, the porogenated precursor/ATRP films show the initial sharp uptake characteristic of micropores and then a smaller increasing slope between 0.1 and 0.2 P/P₀ indicating that pores of increasing size are progressively getting filled at higher pressures. This confirms that a larger pore size distribution is present in the ASF/ATRP films (e.g., in the 1-1.5 nm range). In addition, no evidence is seen to support the possibility of agglomeration of the pores. Despite the fact that the porosity, dielectric constant, and carbon content characteristics of the porogenated precursor/ATRP films were more favorable compared to that of comparative DEMS/ATRP films, these films also showed higher shrinkage and lower modulus as shown in Table 4 compared to the DEMS/ATRP films and the films deposited with the porogenated precursor alone.

### Example 3

### Films Deposited Using Structure Former Precursor, Porogenated Precursor, and Porogen Precursor

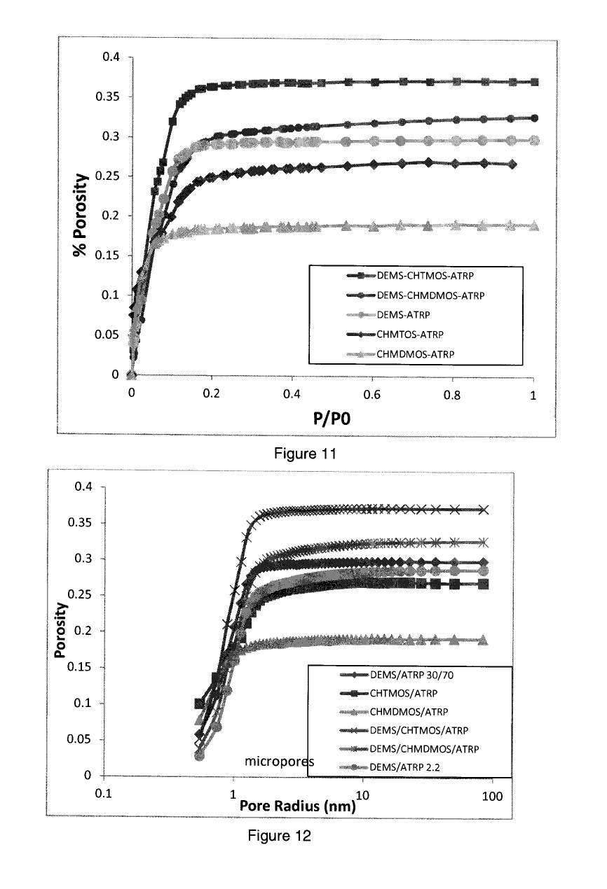

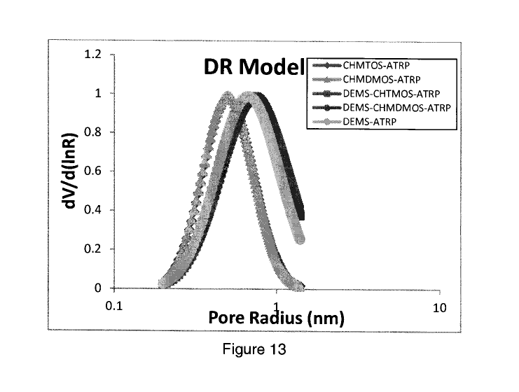

Since DEMS is reported as the structure former providing maximum mechanical strength OSG films for a given k value (3), the present examples focused on adding DEMS to the porogenated precursor/porogen compositions of Example 2 in an attempt to control film shrinkage and improve mechanical strength. The results of these experiments are provided in the following Table 5 and FIG. 10 through 13. For the following examples unless otherwise specified, the weight percentage ratio for structure former precursor and porogen precursor is 30/70; for structure former precursor, porogenated precursor, and porogen precursor is 15/15/70; and for porogenated precursor and porogen precursor is 30/70.

TABLE 5
Comparison of Properties for Various Compositions Comprising
Porogenated Precursor, Structure Former Precursor (DEMS), and
Porogen Precursor (ATRP)

| | | | | | | Avg pore |
|---|---|---|---|---|---|---|
| | | M | C | % | Porosity | diameter |
| Film | k | (GPa) | at % | Shrinkage | (%) | (nm) |
| DEMS/ATRP | 2.41 | 8.09 | 18 | 22.7 | 29.8 | 12.7 |
| 30/70 | | | | | | |
| DEMS/ | 2.27 | 6.31 | 19.7 | 24.5 | 37.2 | 14 |
| CHTMOS/ | | | | | | |
| ATRP | | | | | | |
| CHTMOS/ATRP | 2.35 | 5.53 | 29 | 36.6 | 26.9 | 9.6 |
| DEMS/ | 2.32 | 6.22 | 21.5 | 28.7 | 32.6 | 14.4 |
| CHMDMOS/ | | | | | | |
| ATRP | | | | | | |
| CHMDMOS/ | 2.36 | 5.48 | 31.2 | 40.7 | 19.1 | 10.2 |
| ATRP | | | | | | |
| DEMS/ATRP | 2.31 | 5.02 | 28.5 | 10.6 | 28.6 | 13.2 |
| k2.2 (25/75) | | | | | | |
| nBTEOS/ATRP | 2.42 | 7.72 | | 20.5 | | |
| DEMS/nBTEOS/ | 2.4 | 7.73 | | 20.8 | | |
| ATRP | | | | | | |
| CHTMOS/ATRP | 2.34 | 5.03 | | 38.6 | | |
| (20/80) | | | | | | |
| DEMS/ | 2.16 | 4.56 | | 24.4 | | |
| CHTMOS/ | | | | | | |
| ATRP | | | | | | |
| DEMS/ATRP | 2.07 | 2.34 | | 37.2 | | |
| (10/90) | | | | | | |

Table 5 reveals that both film shrinkage and mechanical strength can be modulated by addition of DEMS for the k˜2.3 films. Although the total open porosity also increases after the addition of DEMS, no significant increase is seen in the calculated average pore size. Modulus is high and the tradeoff in carbon content is evident.

In summary, Example 1 showed that using the porogenated precursor alone could not produce films with dielectric constants lower than 2.6; however, the mechanical properties and carbon content were promising. Example 2 showed that the use of a separate porogen allowed further lowering of k value, but shrinkage and mechanical strength was compromised in the process. Example 3 showed that the addition of a structure former precursor such as DEMS to the porogenated precursor/porogen composition helped to control shrinkage and increase mechanical strength.

The present invention has been set forth with regard to several preferred embodiments, but the scope of the present invention is considered to be broader than those embodiments and should be ascertained from the claims below.

1. A chemical vapor deposition method for producing a porous organosilica glass film represented by the formula SiᵥO_{w}CₓH_{y}F_{z}, where v+w+x+y+z=100%, v is from 10 to 35 atomic %, w is from 10 to 65 atomic %, x is from 5 to 30 atomic %, y is from 10 to 50 atomic % and z is from 0 to 15 atomic %, said method comprising:
providing a substrate within a reaction chamber; introducing into the reaction chamber reagents comprising a porogenated precursor comprising a silicon atom bonded to a porogen; optionally a structure former precursor selected from the group consisting of an organosilane and an organosiloxane; and optionally a porogen precursor wherein the porogen in the porogenated precursor comprises 10 carbon atoms or less;
applying at least one energy source to the gaseous reagents in the reaction chamber to induce reaction of the gaseous reagents to deposit a preliminary film on the substrate, wherein the preliminary film contains the porogen; and
removing from the preliminary film at least a portion of the porogen to provide the porous film with pores and a dielectric constant less than 2.6.

2. The method of claim 1 wherein the dielectric constant is less than 2.2.

3. The method of claim 1 wherein v is from 20 to 30 atomic %, w is from 20 to 45 atomic %, x is from 5 to 20 atomic %, y is from 15 to 40 atomic % and z is 0.

4. The method of claim 1 wherein the at least one energy source is plasma energy.

5. The method of claim 1, wherein the structure former precursor comprises an organosiloxane is diethoxymethylsilane.

6. The method of claim 5, wherein the organosiloxane comprises diethoxymethylsilane.

7. The method of claim 1, wherein the structure former precursor is a compound represented by one or more of the following:
(a) the formula R¹ₙ(OR²)ₚ(O(O)CR³)₄₋₍ₙ₊ₚ₎Si where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3 and p is 0 to 3;
(b) the formula R¹ₙ(OR²)ₚ(O(O)CR⁴)₃₋ₙ₋ₚSi—O—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R² and R⁶ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3 and m+q≦3;
(c) the formula R¹ₙ(OR²)ₚ(O(O)CR⁴)₃₋ₙ₋ₚSi—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R² and R⁶ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3 and m+q≦3;
(d) the formula R¹ₙ(OR²)ₚ(O(O)CR⁴)₃₋ₙ₋ₚSi—R⁷—SiR³ₘ(O(O)CR⁵)_{q}(OR⁶)_{3-m-q} where R¹ and R³ are independently H or C₁ to C₄ linear or branched, saturated, singly or multiply unsaturated, cyclic, partially or fully fluorinated hydrocarbon; R², R⁶ and R⁷ are independently C₁ to C₆ linear or branched, saturated, singly or multiply unsaturated, cyclic, aromatic, partially or fully fluorinated hydrocarbon, R⁴ and R⁵ are independently H, C₁ to C₆ linear or branched, saturated, singly or multiply unsaturated, cyclic, aromatic, partially or fully fluorinated hydrocarbon, n is 0 to 3, m is 0 to 3, q is 0 to 3 and p is 0 to 3, provided that n+m≧1, n+p≦3, and m+q≦3;
(e) the formula (R¹ₙ(OR²)ₚ(O(O)CR³)₄₋₍ₙ₊ₚ₎Si)ₜCH₄₋ₜ where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3, p is 0 to 3, and t is 2 to 4, provided that n+p≦4;
(f) the formula (R¹ₙ(OR²)ₚ(O(O)CR³)₄₋₍ₙ₊ₚ₎Si)ₜNH₃₋ₜ where R¹ is independently H or C₁ to C₄ linear or branched, saturated, singly or multiply unsaturated, cyclic, partially or fully fluorinated hydrocarbon; R² is independently C₁ to C₆ linear or branched, saturated, singly or multiply unsaturated, cyclic, aromatic, partially or fully fluorinated hydrocarbon, R³ is independently H, C₁ to C₆ linear or branched, saturated, singly or multiply unsaturated, cyclic, aromatic, partially or fully fluorinated hydrocarbon, n is 1 to 3, p is 0 to 3 and t is 1 to 3, provided that n+p≦4; or
(g) cyclic carbosilanes of the formula (CR₁R₃SiR₁R₃)ₓ, where R¹ and R³ are independently H, C₁ to C₄, linear or branched, saturated, singly or multiply unsaturated, cyclic, partially or fully fluorinated, and x is an integer from 2 to 8.

8. The method of claim 1, wherein the structure former precursor is a member selected from the group consisting of diethoxymethylsilane, dimethoxymethylsilane, di-isopropoxymethylsilane, di-t-butoxymethylsilane, methyltriethoxysilane, methyltrimethoxysilane, methyltri-isopropoxysilane, methyltri-t-butoxysilane, dimethyldimethoxysilane, dimethyldiethoxysilane, dimethyldi-isopropoxysilane, dimethyldi-t-butoxysilane, and tetraethoxysilane.

9. The method of claim 1, wherein structure former precursor comprises a mixture of a first organosilicon precursor with two or fewer Si—O bonds with a second organosilicon precursor with three or more Si—O bonds, and the mixture is provided to tailor a chemical composition of the porous film.

10. The method of claim 1 wherein the reagents comprise diethoxymethylsilane and tetraethoxysilane.

11. A composition for depositing porous low dielectric constant film comprising:
(a)(i) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof;
(a)(ii) a structure former precursor selected from the group consisting of diethoxymethylsilane, dimethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trim ethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof; and
(b) a porogen precursor selected from the group consisting of: alpha-terpinene, limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes, bicycloheptadiene (BCHD), and decahydronaphthele.

12. The composition of claim 11 wherein the structure former precursor is diethoxymethylsilane and the porogen precursor is alpha-terpinene.

13. The composition of claim 11 provided in a kit, wherein the porogenated precursor, the structure former precursor, and the porogen precursor are maintained in separate vessels.

14. The composition of claim 13 wherein at least one of the vessels is a pressurizable stainless steel vessel.

15. The composition of claim 13 wherein the porogen and the precursor are maintained in a single vessel having a separation means for maintaining the porogens and the precursor separate.

16. A composition for depositing porous low dielectric constant film comprising:
a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilylethyl)cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof.

17. A composition for depositing porous low dielectric constant film comprising:
(a)(i) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 142-(trimethoxysilyl)ethyl]cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and
(a)(ii) a structure former precursor selected from the group consisting of diethoxymethylsilane, dimethoxymethylsilane, di-isopropoxymethylsilane, di-t-butoxymethylsilane, methyldiethoxysilane, methyltriethoxysilane, methyltrimethoxysilane, methyltri-isopropoxysilane, methyltri-t-butoxysilane, dimethyldimethoxysilane, dimethyldiethoxysilane, dimethylethoxysilane, dimethyldi-isopropoxysilane, dimethyldi-t-butoxysilane, tetraethoxysilane, methylsilane, dimethylsilane, trim ethylsilane, tetramethylsilane, phenylsilane, cyclohexylsilane, tert-butylsilane, ethylsilane, diethylsilane, methyltriacetoxysilane, methyldiacetoxysilane, methylethoxydisiloxane, tetramethylcyclotetrasiloxane, octamethylcyclotetrasiloxane, dimethyldiacetoxysilane, bis(trimethoxysilyl)methane, bis(dimethoxysilyl)methane, tetraethoxysilane, triethoxysilane, trimethylphenoxysilane, phenoxysilane, ditertbutylsilane, diethyoxysilane and mixtures thereof.

18. A composition for depositing porous low dielectric constant film comprising:
(a) a porogenated precursor selected from the group consisting of: octyltriethoxysilane, octyltrimethoxysilane, cyclooctyltriethoxysilane, cyclooctyltrimethoxysilane, octyltrimethoxysilane, octnyltriethoxysilane, hexyltriethoxysilane, isobutyltriethoxysilane, methylcyclohexyldiethoxysilane, cyclooctyltriethoxysilane, butyltriethoxysilane, cyclohexanetrimethoxysilane, cyclohexyltrimethoxysilane, cyclohexylmethyldimethoxysilane, neobutyltriethoxysilane, cyclopentyltriethoxysilane, cyclopentylmethyltriethoxysilane, (5-bicycloheptenyl)triethoxysilane, (5-bicycloheptenyl)methyldiethoxysilane, (5-bicycloheptenyl)dimethylethoxysilane, (5-bicycloheptenyl)trimethylsilane, (5-bycloheptyl)methyldiethoxysilane, (5-bicycloheptyl)dimethylethoxysilane, (5-bicycloheptyl)trimethylsiane, (5-bicycloheptyl)dimethylchlorosilane, cyclohexylmethyldimethoxysilane, isobutylmethyldimethoxysilane, 1-[2-(trimethoxysilylethyl)cyclohexane-3,4-epoxide, 1,1, -dimethyl-1-silacyclopentane, (2-cyclohexen-1-yloxy)trimethylsilane, (cyclohexyloxy)trimethylsilane, 2,4-cyclopentadie-1-yltrimethylsilane, 1,1-dimethylsilacyclohexane, and combinations thereof; and
(b) a porogen precursor selected from the group consisting of: alpha-terpinene, limonene, cyclohexane, cyclooctene, cycloheptene, cyclooctane, cyclooctadiene, cycloheptane, cycloheptadiene, cycloheptatriene, 1,2,4-trimethylcyclohexane, 1,5-dimethyl-1,5-cyclooctadiene, camphene, adamantane, 1,3-butadiene, gamma-terpinene, dimethylhexadiene, ethylbenzene, decahydronaphthalene, 2-carene, 3-carene, vinylcyclohexene and dimethylcyclooctadiene, substituted dienes, bicycloheptadiene (BCHD), and decahydronaphthele.
